(19) United States
(12) Patent Application Publication
(10) Pub. No.: US 2019/0273171 A1
(43) Pub. Date: Sep. 5, 2019

(54) SOLAR WINDOW

(71) Applicant: BRIGHT NEW WORLD AB, Lund (SE)

(72) Inventors: Håkan BERGSTRÖM, Torna-Hällestad (SE); Thomas CRAVEN-BARTLE, Sådra Sandby (SE); Mats Peter WALLANDER, Lund (SE); Ola WASSVIK, Lammhult (SE)

(73) Assignee: Bright New World AB, Lund (SE)

(21) Appl. No.: 16/304,706

(22) PCT Filed: May 30, 2017
(86) PCT No.: PCT/EP2017/062996

§ 371 Date: Nov. 27, 2018

(30) Foreign Application Priority Data
May 30, 2016 (SE) 1650753-5

(51) Int. Cl. H01L 31/055; H01L 31/054; H01L 31/048; H01L 31/056

(52) U.S. Cl. CPC H01L 31/055; H01L 31/0547; H01L 31/056; H01L 31/0481; H01L 31/0549

(57) ABSTRACT

A solar panel is described, the solar panel comprising a light transparent panel, a photo luminescent layer configured to absorb light of a first wavelength spectrum and emit light at a photo luminescent wavelength into the light transparent panel to propagate in the light transparent panel via total internal reflection, one or more photovoltaic components located at a periphery of the light transparent panel and configured to receive light propagating in the light transparent panel via total internal reflection and convert said light to electrical energy.

### TECHNICAL FIELD

The invention relates generally to solar panels, configured to convert incident electromagnetic energy into electrical energy. In particular, the invention relates to solar windows.

### BACKGROUND

Different technologies for converting solar radiation energy into other forms of useful energy have been suggested throughout the years. While various solutions for converting solar energy into thermal energy have been developed, the most challenging objective has been to convert radiation energy into electrical energy. In such a scenario, a solar panel generally refers to a photovoltaic module, including a set of photovoltaic (PV) cells, or solar cells, that generally are electrically connected.

The most prevalent material for solar panels is silicon (Si), and a typical Si PV cell is composed of a thin wafer consisting of an ultra-thin layer of phosphorus-doped (n-type) silicon on top of a thicker layer of boron-doped (p-type) silicon. An electrical field is created near the top surface of the cell where these two materials are in contact, called the p-n junction. When sunlight strikes the surface of a PV cell, this electrical field provides momentum and direction to light-stimulated charged carriers, i.e. electrons or holes, resulting in a flow of current when the solar cell is connected to an electrical load. In a single-junction PV cell, only photons whose energy is equal to or greater than the band gap of the cell material can free an electron for an electric circuit. In other words, the photovoltaic response of single-junction cells is limited to the portion of the sun's spectrum whose energy is above the band gap of the absorbing material, and lower-energy photons are not used. Furthermore, excessive energy above the band gap will be lost as heat.

Solar panels with several p-n junctions of different band gap are known. Such multi junction cells have primarily been developed based on thin film technology. As an example, such a cell may comprise multiple thin films, each essentially a solar cell grown on top of each other by metalorganic vapour phase epitaxy. A triple-junction cell, for example, may consist of the semiconductors: GaAs, Ge, and GaInP. Each layer thus has a different band gap, which allows it to absorb electromagnetic radiation over a different portion of the spectrum.

Another solution is suggested in U.S. Pat. No. 8,664,513, in which solar modules including spectral concentrators are described. A solar module includes an active layer including a set of photovoltaic cells, and a spectral concentrator optically coupled to the active layer and including a luminescent material that exhibits photoluminescence in response to incident solar radiation with a peak emission wavelength in the near infrared range.

In spite of extensive research in the area, solar panel technology still faces the challenge of improving efficiency in terms of energy conversion, and the balance of energy gained compared to cost of development and installation. An aspect of this problem is the generation of heat in solar panels, which both means that a part of the incident radiation energy is not successfully converted into electrical energy, and which furthermore, might be detrimental to the function and lifetime of the solar panel. Furthermore, existing solar panels are aesthetically unattractive.

### SUMMARY OF THE INVENTION

In an aspect of the invention, there is provided a solar panel comprising a light transparent panel, a photo luminescent layer configured to absorb light of a first wavelength spectrum and emit light at a photo luminescent wavelength into the light transparent panel to propagate in the light transparent panel via total internal reflection, one or more photovoltaic components located at a periphery of the light transparent panel and configured to receive light propagating in the light transparent panel via total internal reflection and convert said light to electrical energy.

In another aspect of the invention, there is provided a solar panel arrangement, comprising a solar panel of any preceding claim, a backing panel arranged opposite rear surface of light transparent panel, and a medium arranged between rear surface of light transparent panel and the backing panel, wherein the medium has a refractive index of less than 1.1.

### DESCRIPTION OF THE FIGURES

FIG. 1 shows a side view of an embodiment of the invention.

FIG. 2a shows a side view of an embodiment of the invention comprising colour correction filters.

FIG. 2b shows a front view of an embodiment of the invention comprising colour correction filters.

FIGS. 3a, 3b, and 3c shows a side view of embodiments of the invention.

FIG. 4 shows a side view of a multi-layered embodiment of the invention.

FIG. 5a shows a side view of an embodiment of the invention comprising light blocking components.

FIG. 5b shows a front view of an embodiment of the invention comprising light blocking components.

### DETAILED DESCRIPTION OF THE EMBODIMENTS

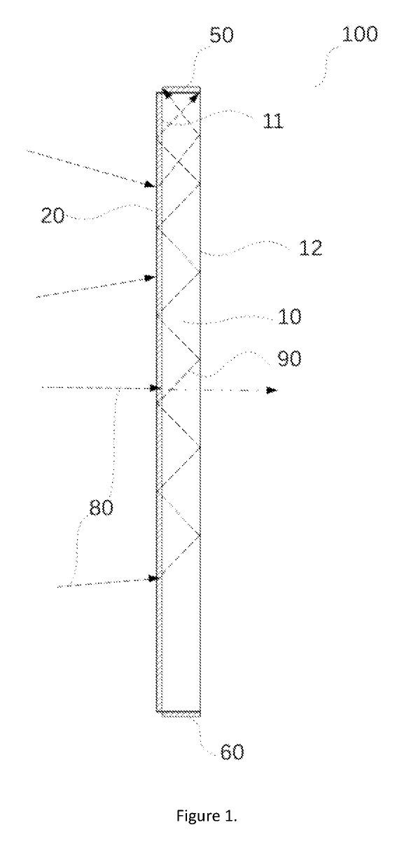

FIG. 1 shows a solar panel 100 comprising a light transparent panel 10, a photo luminescent layer 20 and a photovoltaic component (50, 55, 60, or 70). Incident light 80 is received by the photo luminescent layer and a portion of the received light is absorbed and converted to light having a photo luminescent wavelength. Photo luminescent light may be emitted at different angles, with respect to the incident light, e.g. isotropically. A portion of the converted light is emitted into the light transparent panel at an angle causing the light 90 to propagate by total internal reflection within the light transparent panel. The light propagates by total internal reflection until reaching a photovoltaic component fixed and index matched to the light transparent panel, wherein the light is transmitted to the photovoltaic component and absorbed to generate an electrical current. The photovoltaic component is arranged at the periphery of the light transparent panel. This advantageously allows light energy to be collected and converted to electricity while providing a clear and unobstructed view through the light transparent panel, enabling the light transparent panel to be used as a window.

In an alternative embodiment, the photovoltaic component comprises one or more bars overlaid onto a single pain of glass so as to split the single pane into two visible panes. In such an embodiment, an observer sees two smaller window panes separated by a vertical bar where the photovoltaic component is located.

The photo luminescent layer 20 may be configured to convert incident light of shorter wavelengths, such as from the sun or other light source, to light of at least one longer wavelength λPL. More particularly, the photo luminescent layer 20 is configured to emit light at a photo luminescent wavelength λPL upon absorption of light of shorter wavelengths. This is accomplished by means of the incorporation of a photo luminescent material in a suitable carrying matrix, such as a polymer film, in the photo luminescent layer 20. The photo luminescent material may be realized by means of dye, but in an embodiment the photo luminescent material comprises quantum dots, examples of which will be outlined in greater detail further below.

The photo luminescent layer 20 is preferably configured to emit photo luminescent light, or in other words down-convert light incident upon it into light, of one or more wavelengths λ PL, adapted for absorption by solar cells for conversion into electrical energy.

In one embodiment, the photo luminescent layer 20 is configured to operate together with a photovoltaic component (50, 55, 60, or 70) comprising single junction solar cells, having a band gap corresponding to a maximum wavelength λC. In such an embodiment, the photo luminescent layer 20 is preferably configured to emit light with a single peak of emission, i.e. light of one wavelength λPL≤λC, i.e. of corresponding or larger energy than the band gap of that single junction.

In an embodiment where photo luminescent layer 20 is configured to operate together with a single junction Si solar cell having a band gap of 1.1 eV and a maximum detection wavelength λC of 1100 nm, the photo luminescent wavelength of light emitted from photo luminescent layer 20 is configured to be within the range of 800-1100 nm. A photo luminescent wavelength within 200 nm of the detection wavelength advantageously minimizes the amount of energy lost as waste heat. Most preferably, said photo luminescent wavelength has an emission peak of 950+/−50 nm for a high efficiency cell, or a peak of 850+/−50 nm for a low efficiency cell.

In an embodiment, efficient spectral concentration, or light conversion, is realized by means of including a layer of quantum dots (QDs) in the photo luminescent layer 20, due to their stable nature as compared to dyes. QDs are well described in the art of nanophysics, and so are several known properties. One specific optical feature of QDs is the emission of photons under excitation, and the wavelength of the emitted light. One photon absorbed by a QD will yield luminescence, in terms of fluorescence. Due to the quantum confinement effect, QDs of the same material, but with different sizes, can emit light of different wavelengths. The larger the dot, the lower the energy of the emitted light. As indicated by its name, a QD is a nano-sized crystal e.g. made of semiconductor materials, small enough to display quantum mechanical properties. Typical QDs may be made from binary alloys such as cadmium selenide or cadmium sulphide (II-VI elements), indium arsenide or indium phosphide (III-V elements), and lead selenide (IV-VI elements), or made from ternary alloys such as cadmium selenide sulphide. It is possible to grow a shell of another material with a different band gap around the core QD region, so-called core-shell structures, e.g. with cadmium selenide in the core and zinc sulphide in the shell.

One of the two main advantages with modern QDs is the high External Quantum Efficiency (EQE) achieved. The physical mechanisms behind this high EQE may involve multi-exciton/photon generation processes wherein e.g. one absorbed photon of energy E is converted into more than one luminescent photon, e.g. two photons having half the energy of the absorbed photon (E/2) at an efficiency of e.g. 95%, see e.g. Chapters 9 & 103 of Quantum Dot Solar Cells Eds. Wu & Wang by Springer.

The QDs may be of core, core/shell or giant core/shell type, typically with a surrounding polymeric. In an embodiment, the QDs are of a core/shell structure, which are suitable for infusion in a carrier material, e.g. a PET film, and still keep its high quantum efficiency.

Alternatives to the carrier, or matrix, material may include PMMA (Poly(methyl methacrylate)), PET, epoxy resins etc. For stability reasons, the luminescent material normally needs to be well encapsulated from the environment. The luminescent material may be designed with additives in order to reduce degradation during shelf-time, application, and embedding, as well as to prolong the lifetime of the finished QD-film. This can be achieved by using a protective environment such as e.g. dried nitrogen. More preferably, luminescent material is encapsulated in a polymer. Another option for the photo luminescent layer 20 is to have a diffusion barrier (e.g. a dielectric layer) on each side of the layer to maintain the function of the luminescent material, which may otherwise be adversely affected by moisture and oxygen. The diffusion barriers can of course be put elsewhere in the stack but an advantage of putting it on the photo luminescent layer 20 itself is that the photo luminescent layer 20 can then be produced in one location and shipped to another place for assembly. Typical diffusion barriers can be dielectric coatings but many other options exist. As one example, PTFE (Polytetrafluoroethylene) of a suitable quality can act as a diffusion barrier, e.g. CYTOP®, which is an amorphous fluoropolymer. In one embodiment, the luminescent material is printed onto a thin PTFE film and then coated with another layer of PTFE so that the luminescent material is sealed within a PTFE structure protecting it from the environment while maintaining high optical clarity and good mechanical properties. The general function of incorporation of QDs suspended in a polymer film has been suggested by Nanosys Inc., together with 3M, though for a quite different application. They provide a QD film (QDEF—Quantum Dot Enhancement Film) which replaces a traditional diffuser film of a backlight unit used in displays. In their solution, blue LEDs are used to inject light into a backlight light guide, and part of the blue light is then shifted to emit green and red in the QDEF to provide tri-chromatic white light. As photo luminescent light typically has isotropical scattering, some of the light travelling towards the rear surface 12 at angles from the normal of the top surface less than that required for total internal reflection may leave through rear surface 12 resulting in optical loss. In one embodiment, the refractive index of the carrier material is between 1.5 and 2. This advantageously reduces the amount of light lost through the rear surface 12, especially if the layers below the carrier material layer have higher refractive indexes than the carrier material.

In one embodiment, light conversion sheet 10 is coated with a barrier coating of SiO—SiO2, MgF2. By proper selection of layer thickness, this barrier coating will also serve as an anti-reflection coating as well as improving scratch resistance. In one embodiment, the optical thickness of the layer is typically ¼ wavelength of the light to be transmitted.

In the embodiments disclosed herein, the core of the QDs, configured in sizes to emit at a suitable wavelength λPL with respect to a predetermined solar cell type. Where more than one type of solar cells is employed, or if they comprise more than one junction, QDs of different sizes may be included in the luminescent material, and potentially also of different materials. Going forward, reference will mainly be made to embodiments configured for use with single junction solar cells, and hence a single peak emission wavelength λPL for the photo luminescence.

As mentioned, the luminescent material of the photo luminescent layer 20 is configured to emit photo luminescent light of an energy that is greater than the band gap of a predetermined solar cell type. Preferably, the QDs of the photo luminescent layer 20 are configured to emit light at a peak wavelength λPL in the near infrared region (NIR). In one non-limiting embodiment, the solar panel 100 is configured to operate with single junction Si cells with a band gap corresponding to a wavelength λC of about 1.1 μm. In an embodiment, the photo luminescent layer 20 is configured to emit light at an emission peak of 950+/−50 nm.

An anti-reflective (AR) coating (not shown in figures) is an optional layer that can be placed on the front surface 11 to reduce Fresnel reflections off the front surface. The AR coating can be made in one single layer or multiple layers depending on the desired reduction in front reflectance, and the range of incident angles over which the cell will operate. The AR coating can also act as a diffusion barrier to protect the QD material from moisture and oxidation, if the photo luminescent layer 20 itself does not include this function.

In one embodiment, the light transparent panel 10 comprises glass having an extinction coefficient of a maximum of 1 m⁻¹ for the wavelength span 800-1100 nm. This advantageously allows the converted light to propagate in the light transparent panel 10 with minimal losses due to absorption. One example of such glass is low iron, high Fe3+ ion glass, such as Tirex glass from AGC or Iris glass from Corning which are low iron content glasses where most of the iron ions have been oxidized to Fe3+ ions, with extinction coefficients below 0.5 m⁻¹. In order to achieve a low iron soda lime glass with favourable and strong reduction in the NIR absorption at 800-1100 nm below 0.5 m⁻¹, as much as possible of the Fe 2+ ion content should be changed to Fe 3+, as well as introducing other metal ions where necessary. This may result in a colour tint, depending on the reduction method used, that would normally be aesthetically unacceptable. However, in embodiments described below, the aesthetically unacceptable tint may be compensated for using a colour correction film.

In one embodiment, the photo luminescent layer 20 comprises a layer of quantum dots printed to a front 11 and/or rear surface 12 of the light transparent panel 10.

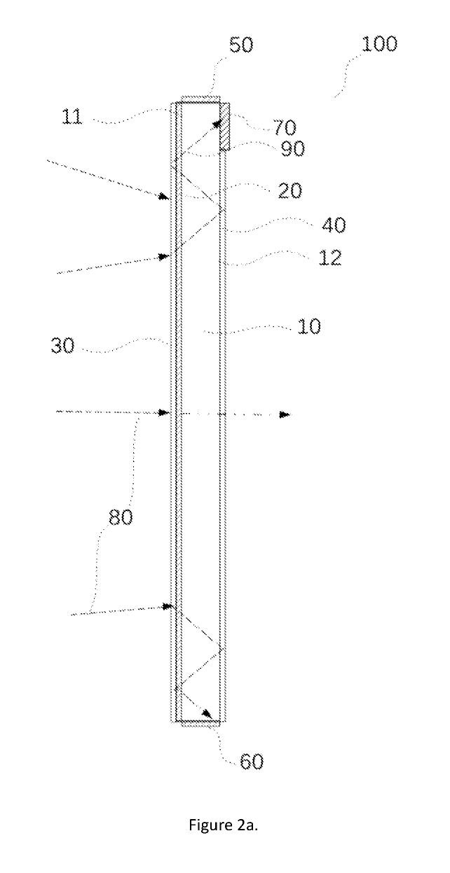

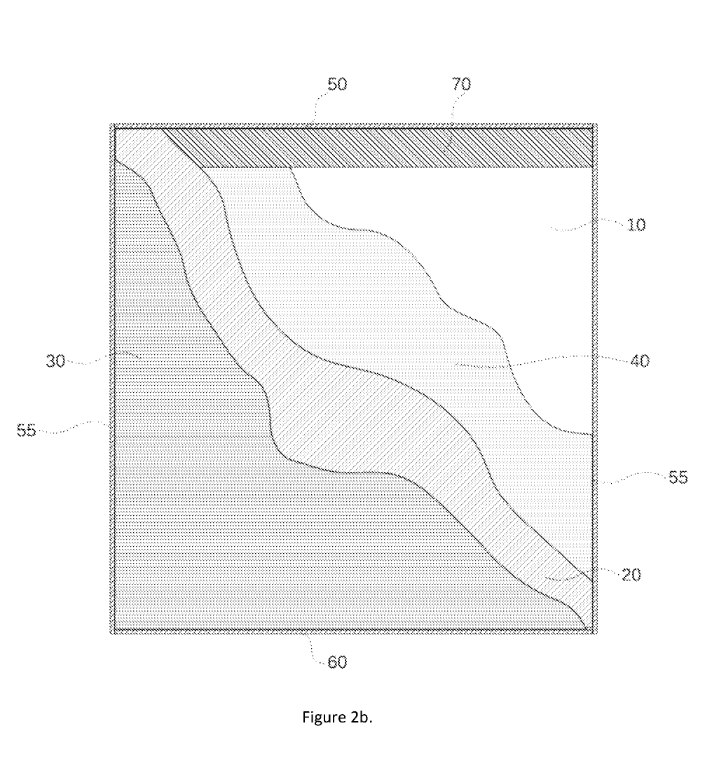

In one embodiment shown in FIGS. 1, 2a and 2b, one or more photovoltaic components are optically connected to a side edge (50, 55, 60) of the light transparent panel 10. Preferably, the components are tiled to reduce wafer spill and minimize thermal stress. For serial interconnection of photovoltaic components, the current produced by each photovoltaic component should be similar. Thus, balancing the length of the photovoltaic components to the light distribution will be optimal, i.e. longer (larger) cells at the edges than at the mid of the window edges. In another embodiment shown in FIG. 2a, one or more photovoltaic components are optically connected to a front (11) or rear surface (12) of the light transparent panel (10). This may be in combination photovoltaic components are optically connected to a side edge or as an alternative. This has the advantage of making it easier to frame the window without interfering optically. Where the light transparent panel (10) is a window, the photovoltaic components are favourably placed proximal to a top edge of the light transparent panel 10 so that they are in the shade and therefore cooler. In this position, they will also be less conspicuous from an end user point of view.

The photovoltaic components are preferably optically mounted to light transparent panel (10) using optically clear adhesive or silicone. E.g. EVA (ethylene vinyl acetate), Dow corning PV-6100.

In one embodiment, reflector components are arranged at the peripheral edges (e.g. at the positions indicated by 50, 55, 60 in FIGS. 2a and 2b) of the light transparent panel 10 and configured to reflect light within the light transparent panel 10. The reflector components may be reflective diffusers configured to reflect and diffuse light within the light transparent panel 10.

A reflective, non-absorbing, colour correction film may be used on front surface 11, rear surface 12 or both surfaces on the same window as the photo luminescent layer. This will have the combined effect of providing both the colour compensation for an inside or outside observer (the design will differ depending on who the tint is designed for) as well as increasing the generated power by allowing the reflected spectra to have a second chance of being absorbed by the photo luminescent film. The reflecting, non-absorbing, colour correcting film may e.g. be constructed by application of a multilayer coating or graded index rugate-type of reflectance coating.

In one embodiment shown in FIG. 2a, the solar panel window 100 comprises the reflective, non-absorbing, colour correcting filter 30 mounted facing front surface 11.

In one embodiment a reflective, non-absorbing, colour correction filter 40 may also be mounted facing rear surface 12, either in combination with colour correction filter 30 or alone. A colour correction filter 40 may be configured in the same way as colour correction filter 30. Alternative, in an embodiment combining colour correction filter 30 and 40, colour correction filter 40 may be configured to correct different parts of the light spectrum in order to provide a complementary colour correction. The colour correcting filter is configured to filter light of one or more wavelength ranges, such that light passing through photo luminescent layer 20, light transparent panel 10, and colour correcting filter 30, is untinted or tinted to an aesthetically desirable colour. An aesthetically desirable colour may be one selected to provide a natural balance of colours to a human observer. As described below, sun glasses and tinted vehicle window tints are suitable examples. The photo luminescent layer 20 will typically have a significant effect of the colour balance of the light passing through it. Therefore, a solar panel window comprising a photo luminescent layer 20 will show a significant colour tint to a viewer looking through the window at the scene beyond. A colour correcting filter 30 advantageously compensates for this effect and allows a viewer to see a view with a desirable tint (if somewhat dimmed) through the window. Typically, the QDs will absorb more light in the blue region than in the red, resulting in a red tint to light passing through a QD layer. The use of a reflective colour correction filters 30/40 also has the advantageous effect of minimizing heat energy passing through light transparent panel 10. Where employed, colour correction filter 40 is configured to compensate for the absorption of the QD layer in order to yield an aesthetic desirable colour. Colour correction filter 40 may also be designed to have a “wavelength cutoff”, reflecting most of the light having a wavelength of above 800 nm. This provides the further advantage that all reflection of invisible light will reduce heat transmitted through the window, reducing AC-costs in hot climate. If mounted on the inside and the wavelength cutoff is just above the visible part of the spectra, there is a second chance to convert some light that was transmitted (or scattered out) in the first pass without visual degradation. Where employed, colour correction filter 30 is preferably configured to have a “wavelength cutoff” reflecting most of the light having a wavelength of above 1050 nm as well as to partly reflect a minimum portion of the visible light in order to achieve an aesthetically desirable colour by itself or in combination with 40.

There are several other ways to create colour correction filters. The simplest type of filter is based on absorption. One way is to give the glass bulk itself a specific tint by controlling or adding different metal ion contents in the glass (Absorbing Pigments Glass). A popular sun glass tint for general use is the Ray Ban G-15 which is designed to imitate the colour sensitivity curve of the human eye. Such a filter may be considered to be an aesthetically desirable filter due to the natural colour effect resulting from the filter. Another way is to add dyes to film substrates (Absorbing Dye Film).

A photo luminescent layer absorbing mainly in the blue region in combination with a colour correcting glass/film with absorption in the red can result in a green tint. One possible drawback with the solutions based on absorption is that the colour correcting glass/film cannot be optically bonded to the power generating glass since it would otherwise absorb the generated PL light and ruin the function.

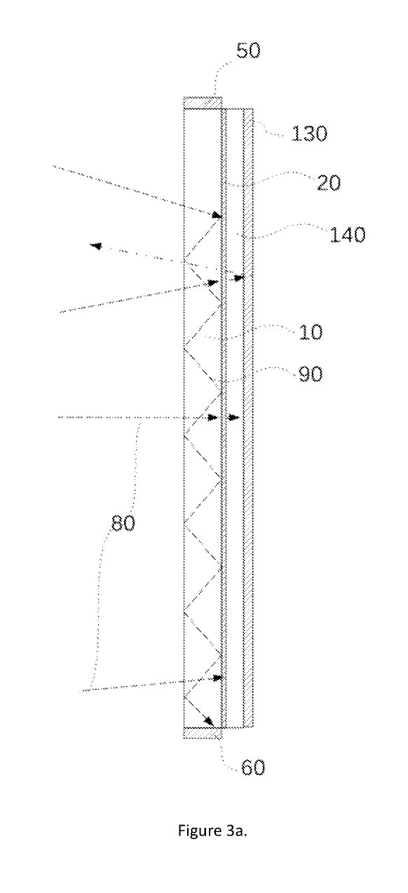

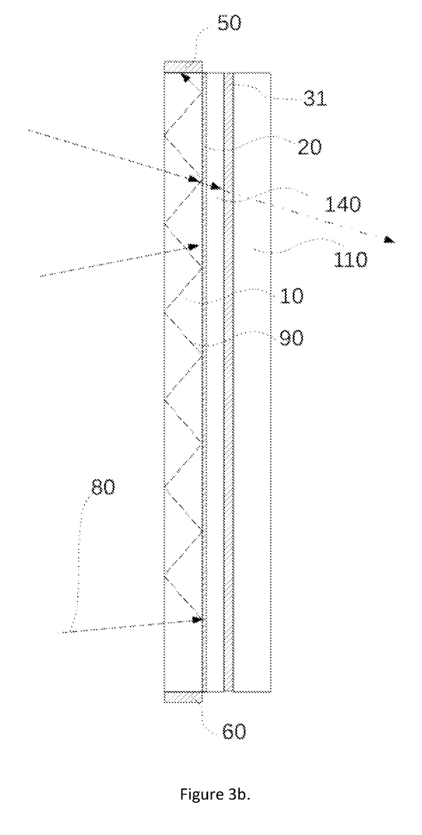

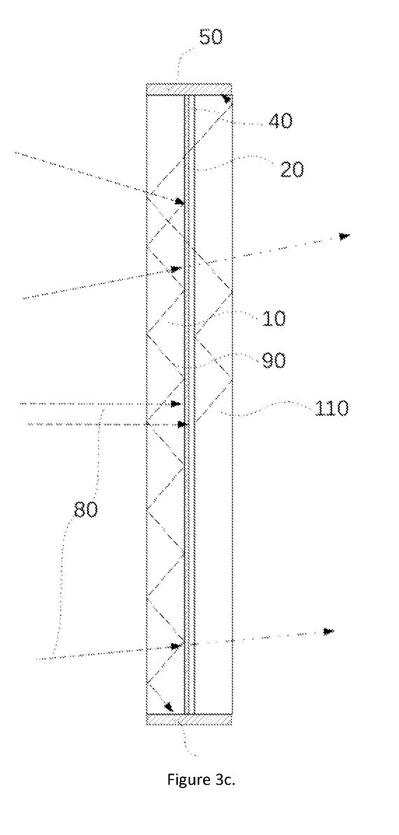

Consequently, as shown in FIG. 3b, an embodiment provides an absorbing colour correction filter 31 arranged on a separate panel 110 and separated by a medium 140 that may comprise an air gap or any material having a refractive index which does not disrupt the total internal reflection of the light propagating within light transparent panel 10.

In an embodiment where solar panel 100 needs to be built using laminated safety glass, photo luminescent layer 20, colour correction filters 30, 40, and any other film layers can be used as the lamination layer in-between two glass sheets. In the embodiment shown in FIG. 3c, light transparent panel 10 forms a first glass sheet, with the second glass sheet 110 arranged on the far side of the lamination layers. This can be very favourable in e.g. an automotive environment where the windshield, side windows and rear window can be made into electrically generating power sources without reducing safety and performance.

In an embodiment shown in FIG. 3a, the solar panel 100 may also comprise a backing panel 130 arranged opposite rear surface 12 of light transparent panel 10. In this embodiment, a medium is arranged between rear surface 12 and the backing panel 130. The medium may comprise an air gap or any material having a refractive index which does not disrupt the total internal reflection of the light propagating within light transparent panel 10. In the embodiment shown in FIG. 3a, the backing panel 130 may be a photovoltaic component configured to receive light emitted by photo luminescent layer 20 at an angle such that the emitted light does not propagate in light transparent panel 10 and instead exits through surface 12.

In another embodiment, backing panel 130 comprises a coloured material, printed image, or an electronic display apparatus. This effectively provides a panel having an aesthetic or display based purpose, whilst being capable of generating electricity. As described above, the photo luminescent layer 20 may cause a colour tint of light passing through it. Consequently, a viewer of the panel may see a tinted effect. Therefore, in an embodiment of the invention, the coloured material, printed image, or electronic display apparatus are configured to be chromatically compensated in dependence on the absorption spectrum of the photo luminescent layer 20. This will result in an image viewed through solar panel 100 is which is colour compensated. The chromatic compensation may be calculated in the manufacture of the coloured material or printing the printed material. The electronic display may apply a software or hardware based electronic chromatic compensation to the images displayed on the electronic display. The software or hardware based electronic chromatic compensation may be pre-calculated to match the properties of the photo luminescent layer 20.

In one embodiment, backing panel 130 comprises a reflecting surface, allowing an aesthetic mirror effect and/or a recycling of some of the light not absorbed by the photo luminescent layer 20 on the first pass.

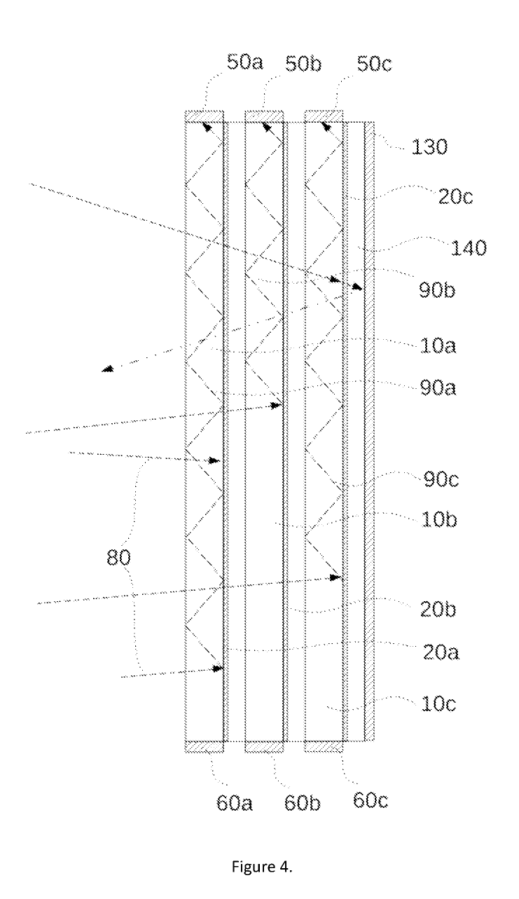

In one embodiment shown in FIG. 4, a plurality of the solar panels 100 described above are arranged sequentially so that unconverted light passing through a first solar panel enters the next solar panel. This configuration allows a double or triple layer solar window, solar wall, or solar car roof where higher efficiency is desired. Efficiency is significantly improved over a single layer embodiment, as the unconverted light from each layer may be converted at the next layer. In an embodiment, the photo luminescent layer 20a, 20b, 20c of each solar panel is configured to absorb and/or emit light of a different wavelength range than the photo luminescent layer 20a, 20b, 20c of the previous solar panel in the sequence. Also preferably, the photovoltaic components of each solar panel have a different band-gap to the photovoltaic components of the previous solar panel in the sequence. The band-gap if each photovoltaic component (e.g. 160a, 160b, 160c or 170a, 170b, 170c) is configured to absorb the photo luminescent light emitted by the corresponding photo luminescent layer 20a, 20b, 20c. This improves the spectral conversion efficiency of the entire solar unit, as a larger total portion of the solar spectrum is absorbed by the solar unit. This embodiment can be combined with the colour correction filters 30,40 and backing plate 140 described above to provide the same advantages as for the single solar panel embodiments. This can be advantageous in e.g. car roofs and other places where appearance is critical for consumer acceptance.

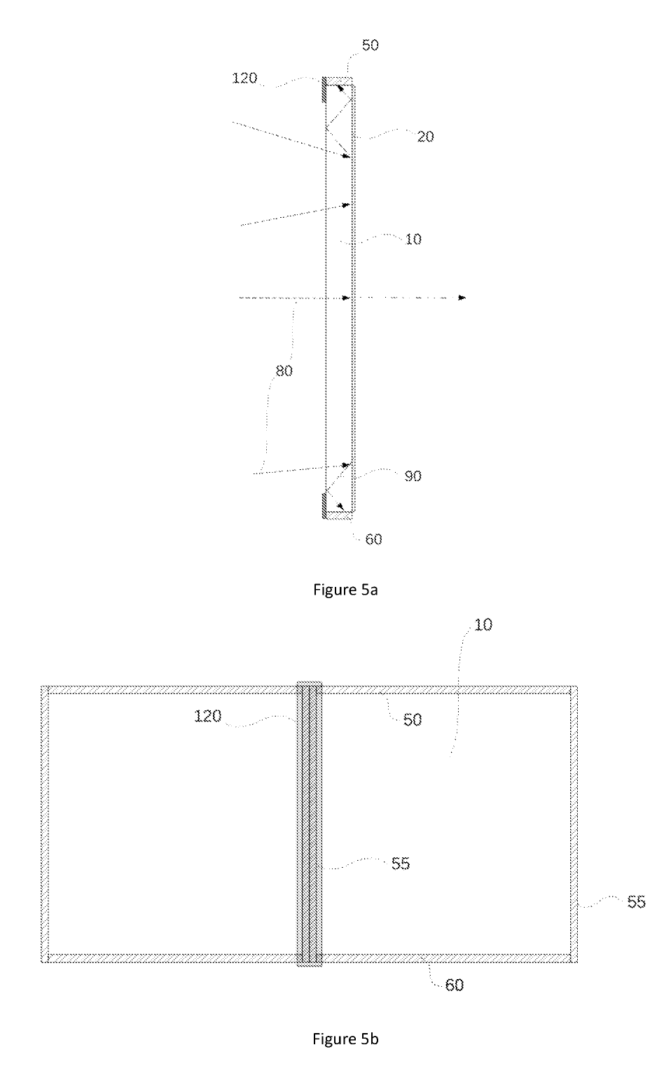

FIGS. 5a and 5b show an embodiment having light blocking components 120 arranged proximal to the periphery of the light transparent panel 10 and preferably opposite front surface 11. Light blocking components 120 are configured to reflect or absorb some or all of the visible light spectrum to provide a shield to the photovoltaic components arranged around the periphery of the light transparent panel from direct sunlight. This advantageously minimizes the warming of the photovoltaic components by the direct sunlight, which would otherwise lead to a reduction of the efficiency of the photovoltaic components for converting light energy to electricity.

In one embodiment where solar panels 100 are tiled together as shown in FIG. 5b, light blocking components 120 are arranged to overlap the tiled solar panels 100, covering proximal edges of the tiled solar panels 100, and reducing manufacturing costs. In this embodiment, the light blocking components 120 can also be advantageously used to cover cabling between solar panels 100 and other electrical and mechanical components. This provides an aesthetically pleasing and consistent appearance to a tiled solar panel arrangement, and allows solar panels 100 in different shapes that are visually pleasing to the eye (e.g. mosaics) that can give an architect many more options for how to design the outside of the building using solar components.

In one embodiment, a solar panel 100 may be curved or shaped to provide facets at multiple angles.

1. A solar panel comprising:
a light transparent panel,
a photo luminescent layer configured to absorb light of a first wavelength spectrum and emit light at a photo luminescent wavelength into the light transparent panel to propagate in the light transparent panel via total internal reflection, and
one or more photovoltaic components located at a periphery of the light transparent panel and configured to receive light propagating in the light transparent panel via total internal reflection and convert said light to electrical energy.

2. The solar panel of claim 1, wherein the photo luminescent wavelength is longer than the wavelengths of the first wavelength spectrum.

3. The solar panel of claim 1, wherein the light transparent panel comprises a transparent medium having an extinction coefficient of a maximum of 1 m⁻1 for the wavelength span 800 nm.

4. The solar panel of claim 1, wherein the light transparent panel comprises low iron glass with an absorption of below 1 m⁻1.

5. The solar panel of claim 4, wherein the low iron glass comprises a low Fe2+ to Fe3+ ratio having absorption below 0.5 m⁻1.

6. The solar panel of claim 1, wherein photo luminescent layer comprises a quantum dot infused film.

7. The solar panel of claim 1, wherein photo luminescent layer comprises a layer of quantum dots printed to a front and/or rear surface of the light transparent panel.

8. The solar panel of claim 1, wherein one or more photovoltaic components are optically connected to a side edge of the light transparent panel.

9. The solar panel of claim 1, wherein one or more photovoltaic components are optically connected to a front or rear surface of the light transparent panel.

10. The solar panel of claim 1, wherein one or more photovoltaic components are optically mounted to light transparent panel using optically clear adhesive or silicone.

11. The solar panel of claim 1, wherein one or more reflector components are arranged at a side edge of the light transparent panel and configured to reflect light within the light transparent panel.

12. The solar panel of claim 11, wherein one or more reflector components are reflective diffuser components configured to reflect and diffuse light within the light transparent panel.

13. The solar panel of claim 1, further comprising one or more reflective, non-absorbing, colour correction filters configured to filter light of one or more wavelength ranges complementary to the one or more wavelength ranges absorbed by photo luminescent layer, such that unconverted light passing through solar panel is aesthetically tinted.

14. The solar panel of claim 13, wherein the one or more colour correcting filters are configured to compensate for a tint resulting from absorption of blue and green light by photo luminescent layer by absorbing or reflecting a complementary portion of the light spectrum.

15. The solar panel of claim 13, wherein a first colour correction filter is arranged facing rear surface of the light transparent panel and comprising a reflective light filter.

16. The solar panel of claim 13, wherein a first colour correction filter is arranged facing rear surface of the light transparent panel with a medium arranged between rear surface and the first colour correction filter comprising a reflecting light filter.

17. The solar panel of claim 13, wherein the first colour correction filter (40) is configured to:
reflect a portion of light having a wavelength of above 800 nm and
at least partially transmit light having a wavelength of below 800 nm.

18-20. (canceled)

21. A solar panel arrangement, comprising a plurality of solar panels of claim 1 tiled so that at least one edge of each solar panel is proximal to an edge of another solar panel, and wherein the one or more light blocking components are arranged to overlap the proximal edges of the solar panels.

22. A solar panel arrangement, comprising a plurality of solar panels of claim 1 arranged sequentially so that unconverted light passing through a first solar panel enters the next solar panel, and wherein the photo luminescent layer of each solar panel is configured to absorb and/or emit light of a different wavelength range than the photo luminescent layer of the previous solar panel in the sequence.

23. The solar panel arrangement of claim 22, wherein the one or more photovoltaic components of each solar panel have a different band-gap to the one or more photovoltaic components of the previous solar panel in the sequence.

24-28. (canceled)
